(19) United States
(12) Patent Application Publication
(10) Pub. No.: US 2010/0327413 A1
(43) Pub. Date: Dec. 30, 2010

(54) HARDMASK OPEN AND ETCH PROFILE CONTROL WITH HARDMASK OPEN

(75) Inventors: Jong Pil Lee, San Ramon, CA (US); Seiji Kawaguchi, San Jose, CA (US); Camelia Rusu, Fremont, CA (US); Zhisong Huang, Fremont, CA (US); Mukund Srinivasan, Fremont, CA (US); Eric Hudson, Berkeley, CA (US); Aaron Eppler, Fremont, CA (US)

Correspondence Address: Beyer Law Group LLP, P.O. BOX 1687, Cupertino, CA, 95015-1687, US

(73) Assignee: LAM RESEARCH CORPORATION, Fremont, CA (US)

(21) Appl. No.: 12/595,234

(22) PCT Filed: May 2, 2008
(86) PCT No.: PCT/US2008/062411

§ 371 Date: Apr. 1, 2010

Related U.S. Application Data
(60) Provisional application No. 61/066,147, filed on May 3, 2007.
(60) Provisional application No. 61/044,012, filed on Apr. 10, 2008.

(51) Int. Cl. H01L 29/00; H01L 21/3065; C23F 1/08; H01L 21/306

(52) U.S. Cl. 257/618; 438/710; 438/725; 156/345.24; 257/E21.218; 257/E29.001

(57) ABSTRACT

A method for opening a carbon-based hardmask layer formed on an etch layer over a substrate is provided. The hardmask layer is disposed below a patterned mask. The substrate is placed in a plasma processing chamber. The hardmask layer is opened by flowing a hardmask opening gas including a COS component into the plasma chamber, forming a plasma from the hardmask opening gas, and stopping the flow of the hardmask opening gas. The hardmask layer may be made of amorphous carbon, or made of spun-on carbon, and the hardmask opening gas may further include O₂.

### BACKGROUND OF THE INVENTION

The present invention relates to etching an etch layer through a mask during the production of a semiconductor device. More specifically, the present invention relates to etching high aspect ratio features through a hardmask during the production of semiconductor devices.

During semiconductor wafer processing, features of the semiconductor device are defined by a patterned mask.

To provide increased density, feature size is reduced. This may be achieved by reducing the critical dimension (CD) of the features, which requires improved resolution.

In forming high aspect ratio features in an etch layer, a hardmask layer may be formed over the etch layer with a mask over the hardmask layer. In addition, Multi-Layer Resist has been widely used in the fabrication process of the high performance ULSI devices. Multi-Layer Resist typically includes a patterning resist layer, a spin-on-glass (SOG) interlayer, and a bottom resist layer. The patterning resist layer may be a photoresist. The bottom resist layer may be a sputtered carbon film, or spun-on carbon film.

### SUMMARY OF THE INVENTION

To achieve the foregoing and in accordance with the purpose of the present invention, a method for etching an etch layer over a substrate and disposed below a hardmask layer disposed below a mask is provided. The substrate is placed in a plasma processing chamber. The hardmask layer is opened by flowing a hardmask opening gas with a COS or CS₂ component into the plasma chamber, forming a plasma from the hardmask opening gas, and stopping the flow of the hardmask opening gas. Features are etched into the etch layer through the hardmask. The hardmask is removed.

In another manifestation of the invention, a method for etching an etch layer over a substrate and disposed below a hardmask layer disposed below a mask wherein the hardmask comprises one of a carbon based material or a silicon doped carbon based component is provided. The substrate is placed in a plasma processing chamber. The hardmask layer is opened by flowing a hardmask opening gas comprising an opening component of at least one of O₂, CO₂, N₂, or H₂ with an additive of COS or CS₂ into the plasma chamber, forming a plasma from the hardmask opening gas, and stopping the flow of the hardmask opening gas. Features are etched into the etch layer through the hardmask. The hardmask is removed.

In another manifestation of the invention, a method for opening a carbon-based hardmask layer formed on an etch layer over a substrate is provided.

The hardmask layer is disposed below a patterned mask. The substrate is placed in a plasma processing chamber. The hardmask layer is opened by flowing a hardmask opening gas including a COS component into the plasma chamber, forming a plasma from the hardmask opening gas, and stopping the flow of the hardmask opening gas. The hardmask layer may be made of amorphous carbon, or made of spun-on carbon, and the hardmask opening gas may further include O₂.

In another manifestation of the invention, a method for opening a spun-on carbon layer in a multi-layer resist mask formed on an etch layer over a substrate is provided. The multi-layer resist mask includes the spun-on carbon layer, an oxide-based material layer disposed over the spun-on carbon layer, and a patterned mask disposed on the oxide-based material layer. The substrate is placed in a plasma processing chamber. The oxide-based material layer is patterned using the patterned mask. The spun-on carbon layer is opened using the patterned oxide-based material layer, by flowing a hardmask opening gas including a COS component into the plasma processing chamber, forming a plasma from the hardmask opening gas, and stopping the flow of the hardmask opening gas. The hardmask opening gas may further include O₂. Features may be etched into the etch layer through the opened spun-on carbon layer, and then, the patterned spun-on carbon layer may be removed in the chamber.

In another manifestation of the invention, an apparatus for etching high aspect ratio features in an etch layer above a substrate and below a carbon containing hardmask below a mask is provided. A plasma processing chamber is provided comprising a chamber wall forming a plasma processing chamber enclosure, a substrate support for supporting a substrate within the plasma processing chamber enclosure, a pressure regulator for regulating the pressure in the plasma processing, chamber enclosure, at least one electrode for providing power to the plasma processing chamber enclosure for sustaining a plasma, at least one RF power source electrically connected to the at least one electrode, a gas inlet for providing gas into the plasma processing chamber enclosure, and a gas outlet for exhausting gas from the plasma processing chamber enclosure. A gas source is in fluid connection with the gas inlet and comprises an opening component source, an etch gas source, and an additive source. A controller controllably connected to the gas source, the RF bias source, and at least one RF power source and comprises at least one processor and computer readable media. The computer readable media comprises computer readable code for opening the hardmask layer, comprising computer readable code for flowing a hardmask opening gas comprising an opening component of at least one of O₂, CO₂, N₂, or H₂ from the opening component source with an additive of COS or CS₂ from the additive source into the plasma chamber, computer readable code for forming a plasma from the hardmask opening gas, and computer readable code for stopping the flow of the hardmask opening gas, computer readable code for etching features into the etch layer through the hardmask, comprising computer readable code for providing an etch gas from the etch gas source, computer readable code for forming a plasma from the etch gas, and computer readable code for stopping the etch gas, and computer readable code for removing the hardmask.

In another manifestation of the invention, an apparatus for etching an etch layer over a substrate using a multi-layer resist mask formed thereon is provided. The multi-layer resist mask includes a spun-on carbon layer formed on the etch layer, an oxide-based material layer disposed on the spun-on carbon layer, and a patterned mask disposed on the oxide-based material layer. The apparatus comprises a plasma processing chamber. The plasma processing chamber includes a chamber wall forming a plasma processing chamber enclosure, a substrate support for supporting a substrate within the plasma processing chamber enclosure, a pressure regulator for regulating the pressure in the plasma processing chamber enclosure, at least one electrode for providing power to the plasma processing chamber enclosure for sustaining a plasma, at least one RF power source electrically connected to at least one electrode, a gas inlet for providing gas into the plasma processing chamber enclosure, and a gas outlet for exhausting gas from the plasma processing chamber enclosure. The apparatus further comprises a gas source in fluid connection with the gas inlet, including a patterning gas source, an opening gas source and an etch gas source, and a controller controllably connected to the gas source, the RF bias source, and at least one RF power source. The controller includes at least one processor and computer readable media. The computer readable media includes computer readable code for patterning the oxide-based material layer using the patterned mask, computer readable code for opening the spun-on carbon layer using the patterned oxide-based material layer which comprises computer readable code for flowing a hardmask opening gas including a COS component into the plasma processing chamber, computer readable code for forming a plasma from the hardmask opening gas, and computer readable code for stopping the flow of the hardmask etching gas. The computer readable media further comprises computer readable code for etching features into the etch layer through the opened spun-on carbon layer which includes computer readable code for providing an etch gas from the etch gas source, computer readable code for forming a plasma from the etch gas, and computer readable code for stopping the etch gas. The computer readable media also comprises computer readable code for removing the patterned spun-on carbon layer.

These and other features of the present invention will be described in more detail below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a high level flow chart of an embodiment of the invention.

FIG. 2 is a schematic view of a plasma processing chamber that may be used for etching.

FIGS. 3A-B illustrate a computer system, which is suitable for implementing a controller used in embodiments of the present invention.

FIGS. 4A-E are schematic views of a stack processed according to an embodiment of the invention.

FIG. 5 is a more detailed flow chart of a step of opening a hardmask layer with an additive.

FIG. 6 is a schematic cross-sectional view of an example of multi-layer resist mask formed on an etch layer formed on a substrate in accordance with one embodiment of the present invention.

FIG. 7 is a high level flow chart of a process of etching an etch layer formed on a substrate using a multi-layer resist mask in accordance with this embodiment of the invention.

FIG. 8 is a schematic view of a plasma processing chamber that may be used for opening and etching in accordance with one embodiment of the present invention.

FIG. 9A is a schematic cross-sectional view of the profile of a spun-on carbon layer after the opening process in accordance with one embodiment of the present invention.

FIG. 9B is a schematic cross-sectional view of the profile of a spun-on carbon layer after a conventional opening process (without COS) as a reference.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

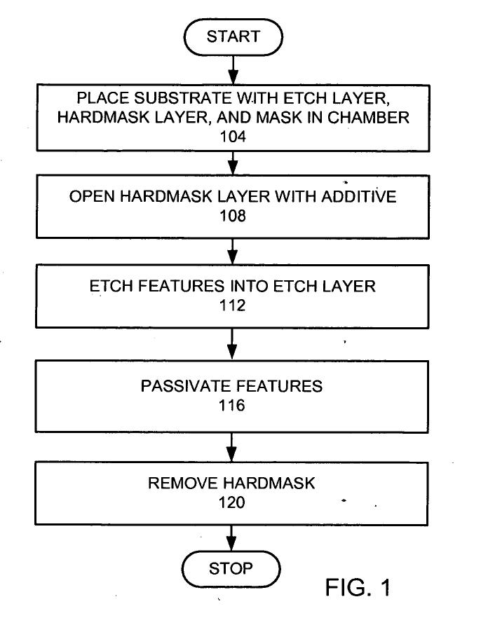

To facilitate understanding, FIG. 1 is a high level flow chart of a process used in an embodiment of the invention. A substrate with an etch layer over which is a hardmask layer over which is a mask is placed in an etch chamber (step 104). The hardmask layer is opened using an opening gas with an additive of COS (carbonyl sulfide) or CS₂ (carbon sulfide) (step 108). Features are etched into the etch layer through the hardmask (step 112). The features are passivated using a passivation gas comprising COS or CS₂ (step 116) during the said etching process. The hardmask is then completely removed (step 120).

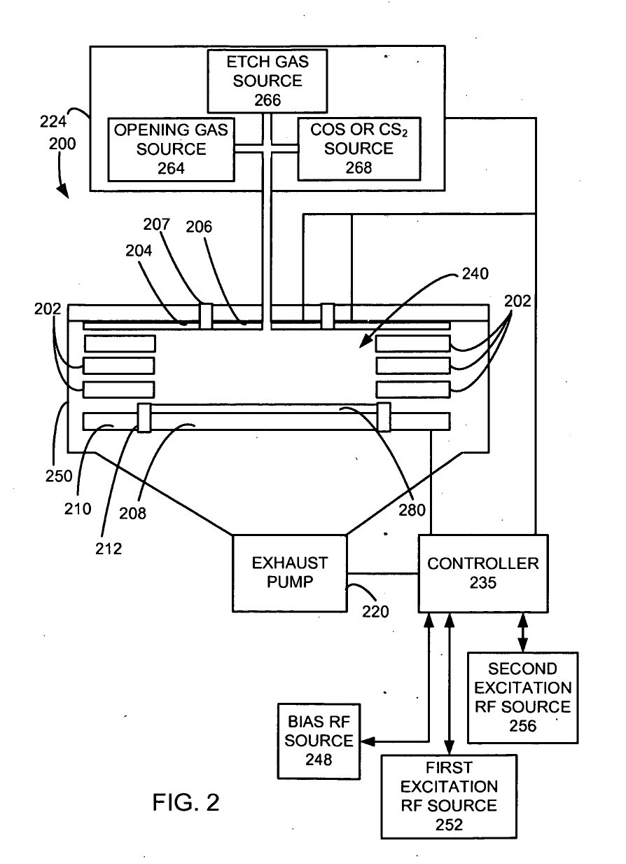

FIG. 2 is a schematic view of a plasma processing chamber (etch reactor) that may be used in practicing the invention. In one or more embodiments of the invention, an etch reactor 200 comprises a top central electrode 206, top outer electrode 204, bottom central electrode 208, and a bottom outer electrode 210, within a chamber wall 250. A top insulator ring 207 insulates the top central electrode 206 from the top outer electrode 204. A bottom insulator ring 212 insulates the bottom central electrode 208 from the bottom outer electrode 210. Also within the etch reactor 200, a substrate 280 is positioned on top of the bottom central electrode 208. Optionally, the bottom central electrode 208 incorporates a suitable substrate chucking mechanism (e.g., electrostatic, mechanical clamping, or the like) for holding the substrate 280.

A gas source 224 is connected to the etch reactor 200 and supplies the etch gas into a plasma region 240 of the etch reactor 200 during the etch processes. In this example, the gas source 224 comprises an opening gas source 264, an etch gas source 266, and a COS or CS₂ source 268, which provide the gases used for the hardmask opening gas.

A bias RF source 248, a first excitation RF source 252, and a second excitation RF source 256 are electrically connected to the etch reactor 200 through a controller 235 to provide power to the electrodes 204, 206, 208, and 210. The bias RF source 248 generates bias RF power and supplies the bias RF power to the etch reactor 200. Preferably, the bias RF power has a frequency between 1 kilo Hertz (kHz) and 10 mega Hertz (MHz). More preferably, the bias RF power has a frequency between 1 MHz and 5 MHz. Even more preferably, the bias RF power has a frequency of about 2 MHz.

The first excitation RF source 252 generates source RF power and supplies the source RF power to the etch reactor 200. Preferably, this source RF power has a frequency that is greater than the bias RF power. More preferably, this source RF power has a frequency that is between 10 MHz and 40 MHz. Most preferably, this source RF power has a frequency of 27 MHz.

The second excitation RF source 256 generates another source RF power and supplies the source RF power to the etch reactor 200, in addition to the RF power generated by the first excitation RF source 252. Preferably, this source RF power has a frequency that is greater than the bias RF source and the first RF excitation source. More preferably, the second excitation RF source has a frequency that is greater than or equal to 40 MHz. Most preferably, this source RF power has a frequency of 60 MHz.

The different RF signals may be supplied to various combinations of the top and bottom electrodes. Preferably, the lowest frequency of the RF should be applied through the bottom electrode on which the material being etched is placed, which in this example is the bottom central electrode 208.

The controller 235 is connected to the gas source 224, the bias RF source 248, the first excitation RF source 252, and the second excitation RF source 256. The controller 235 controls the flow of the etch gas into the etch reactor 200, as well as the generation of the RF power from the three RF sources 248, 252, 256, the electrodes 204, 206, 208, and 210, and the exhaust pump 220.

In this example, confinement rings 202 are provided to provide confinement of the plasma and gas, which pass between the confinement rings and are exhausted by the exhaust pump.

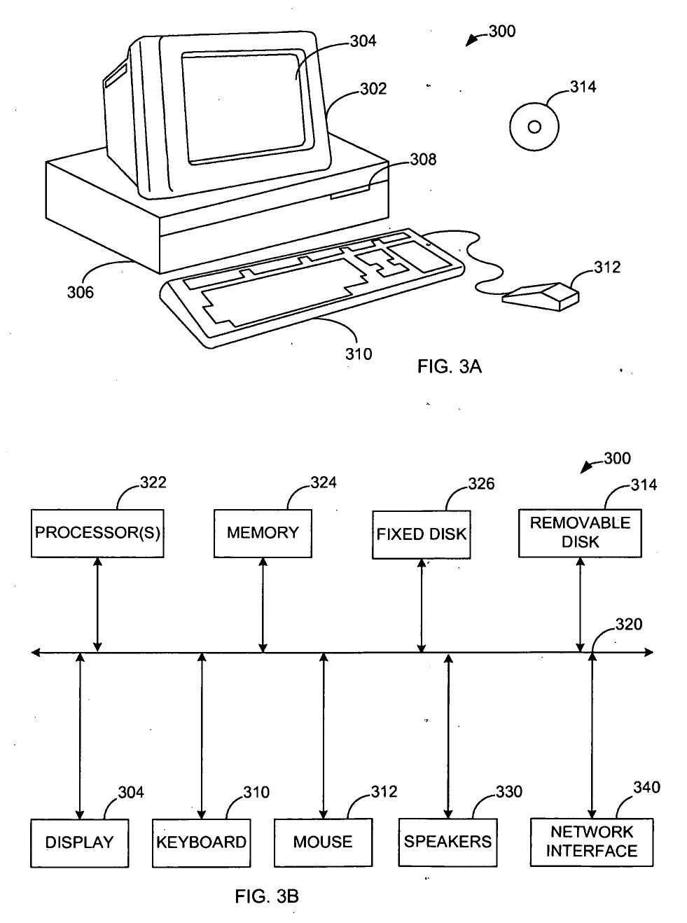

FIGS. 3A and 3B illustrate a computer system, which is suitable for implementing the controller 235 used in one or more embodiments of the present invention. FIG. 3A shows one possible physical form of the computer system 300. Of course, the computer system may have many physical forms ranging from an integrated circuit, a printed circuit board, and a small handheld device up to a huge super computer. Computer system 300 includes a monitor 302, a display 304, a housing 306, a disk drive 308, a keyboard 310, and a mouse 312. Disk 314 is a computer-readable medium used to transfer data to and from computer system 300.

FIG. 3B is an example of a block diagram for computer system 300. Attached to system bus 320 is a wide variety of subsystems. Processor(s) 322 (also referred to as central processing units, or CPUs) are coupled to storage devices, including memory 324. Memory 324 includes random access memory (RAM) and read-only memory (ROM). As is well known in the art, ROM acts to transfer data and instructions uni-directionally to the CPU and RAM is used typically to transfer data and instructions in a bi-directional manner. Both of these types of memories may include any suitable of the computer-readable media described below. A fixed disk 326 is also coupled bi-directionally to CPU 322; it provides additional data storage capacity and may also include any of the computer-readable media described below. Fixed disk 326 may be used to store programs, data, and the like and is typically a secondary storage medium (such as a hard disk) that is slower than primary storage. It will be appreciated that the information retained within fixed disk 326 may, in appropriate cases, be incorporated in standard fashion as virtual memory in memory 324. Removable disk 314 may take the form of any of the computer-readable media described below.

CPU 322 is also coupled to a variety of input/output devices, such as display 304, keyboard 310, mouse 312, and speakers 330. In general, an input/output device may be any of: video displays, track balls, mice, keyboards, microphones, touch-sensitive displays, transducer card readers, magnetic or paper tape readers, tablets, styluses, voice or handwriting recognizers, biometrics readers, or other computers. CPU 322 optionally may be coupled to another computer or telecommunications network using network interface 340. With such a network interface, it is contemplated that the CPU might receive information from the network, or might output information to the network in the course of performing the above-described method steps. Furthermore, method embodiments of the present invention may execute solely upon CPU 322 or may execute over a network such as the Internet in conjunction with a remote CPU that shares a portion of the processing.

In addition, embodiments of the present invention further relate to computer storage products with a computer-readable medium that have computer code thereon for performing various computer-implemented-operations. The media and computer code may be those specially designed and constructed for the purposes of the present invention, or they may be of the kind well known and available to those having skill in the computer software arts. Examples of computer-readable media include, but are not limited to: magnetic media such as hard disks, floppy disks, and magnetic tape; optical media such as CD-ROMs and holographic devices; magneto-optical media such as floptical disks; and hardware devices that are specially configured to store and execute program code, such as application-specific integrated circuits (ASICs), programmable logic devices (PLDs) and ROM and RAM devices. Examples of computer code include machine code, such as produced by a compiler, and files containing higher level of code that are executed by a computer using an interpreter. Computer readable media may also be computer code transmitted by a computer data signal embodied in a carrier wave and representing a sequence of instructions that are executable by a processor.

### Examples

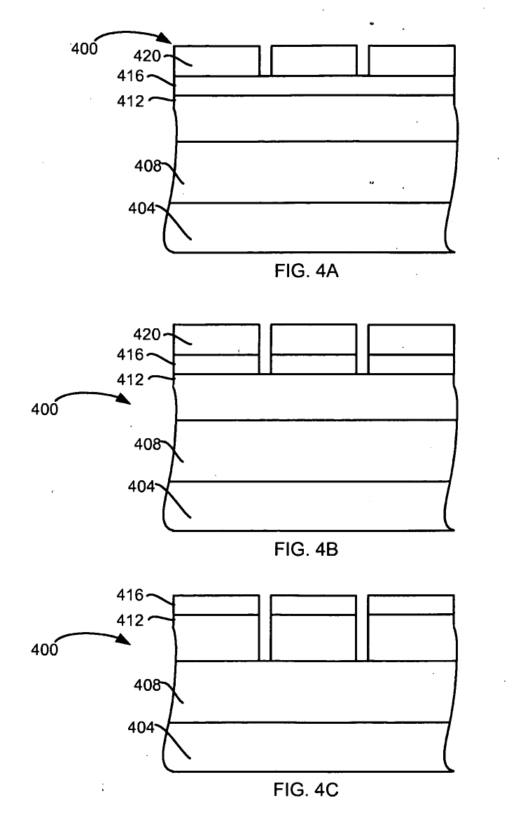

To facilitate understanding of the invention, FIG. 4A is a schematic cross-sectional illustration of a stack 400 with a substrate 404, over which an etch layer 408 is provided, over which a hardmask layer 412 is provided, over which a mask 416 is provided, over which a photoresist mask 420 is provided. In this embodiment of the invention, the substrate 404 is a silicon wafer and the etch layer 408 is a dielectric layer, such as a doped or undoped silicon oxide inorganic or organic based low-k dielectric material, the hardmask layer 412 is amorphous carbon, the mask 416 is silicon oxide (SiO₂) or silicon oxynitride (SiON). In other examples the etch layer is at least one of a silicon dioxide based material, organo-silicate glass, a silicon nitride based material, a silicon oxynitride based material, silicon carbide based material, silicon or poly-silicon material, or any metal gate material. In other examples the hardmask is carbon based material or a silicon based material with a carbon component.

The substrate 404, etch layer 408, hardmask layer 412, and mask 416 are placed in the etch reactor 200 (step 104). The mask 416 is etched through the photoresist mask to pattern the mask 416, as shown in FIG. 4B. Often, the mask 416 comprises of a layer (DARC) or 2 layers (BARC/DARC) (Bottom Anti-Reflective Coating/Dielectric Anti-Reflective Coating). The usual gas to open this type of mask has a fluorocarbon or hydrofluorocarbon based chemistry, with or without Ar and O₂ addition.

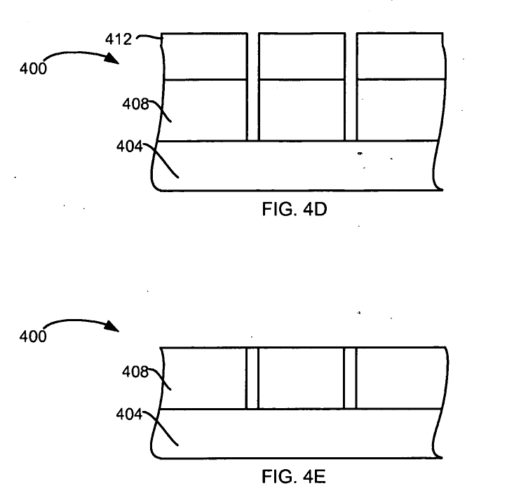

The hardmask layer is opened using a COS or CS₂ additive (step 108). FIG. 5 is a more detailed flow chart of the step of opening the hardmask layer using an COS or CS₂ additive. An opening gas with an additive is flowed into the etch chamber (step 504). In this example, an opening gas comprising O₂, COS, and possibly an inert gas is provided. The opening gas is formed into a plasma (step 508). The plasma is used to open the hardmask. FIG. 4C is a schematic cross sectional view of the stack 400 after the opening process has opened features into the hardmask layer 412. Once the features are opened in the hardmask layer 412, the flow of the opening gas is stopped (step 512). Most likely, during this step, the photoresist (PR) layer gets completely removed.

An example recipe for a hardmask opening provides a chamber pressure of 20 mTorr. The electrostatic chuck temperature is maintained at −10° C. An upper electrode temperature is maintained at 140° C. Alternatively, the electrostatic chuck temperature is maintained at 30° C., and the upper electrode temperature is maintained at 110° C. An opening gas of 200 sccm O₂ and 10 sccm COS is provided. 600 watts at 60 MHz is provided for 52 seconds. For this example recipe, the etch rate of removing the hardmask is around 6000 A/min.

Features are etched into the etch layer through the opened hardmask layer (step 112). The recipe used depends on the type of material that has to be etched. For TEOS, BPSG, low k− dielectric, FSG, SiN, etc., different process recipes are required.

FIG. 4D is a schematic cross-sectional view of the stack 400 after the features have been etched into the etch layer 408. The mask 416 may be the same material or may have similar etch properties as the etch layer 408. As a result, the selectivity between the etch layer 408 and the mask 416 may be very low or approximately 1:1, which would cause this mask to be etched away during the etching of features in the etch layer 408. Because the hardmask layer 412 has different etch properties than the etch layer 408, the etch layer 408 is selectively etched with respect to the hardmask.

In other embodiments of the invention, the etch layer may be undoped or doped silicon dioxide based material (e.g. TEOS, BPSG, FSG etc), organo-silicate glass (OSG), porous OSG, silicon nitride based material, silicon oxynitride based material, silicon carbide based material, low k− dielectric or any metal gate material.

In this example, the etched features are passivated (step 116). In this example, a chamber pressure of 20 mTorr. The electrostatic chuck temperature is maintained at −10° C. An upper electrode temperature is maintained at 140° C. A passivating gas of 200 sccm O₂ and 10 sccm COS is provided. 600 watts at 60 MHz is provided. Without being bound by theory, it is believed that the passivation provides a barrier that protects the etch layer during stripping or removing the hardmask layer. Most likely the S bonds to carbon from the amorphous carbon forming structures containing C—S or C—S—S—C bonding. It is believed that this type of compound has a good etch resistance.

The hardmask is removed (step 120). A normal organic layer stripping process, such as providing an O₂ stripping gas may be used. The passivation layer may be used to protect low-k dielectric and/or organic dielectric layers during the stripping. In the alternative, an additive of COS or CS₂ may be added to the stripping gas to further provide a protective layer during the stripping process. A wet-clean process may be used after the removal of the hardmask to remove any remaining passivation layer, without damaging the etch layer. FIG. 4E is a schematic cross-sectional view of the stack after the hardmask layer has been stripped.

In one example, the opening gas is fluorine free. Whether fluorine is used depends on the material of the hardmask. A fluorine free opening gas is able to open a hardmask layer containing no silicon. In another example, where the hardmask layer has a silicon component, the opening gas has a fluorine component. The fluorine composition has to be properly adjusted in order to have enough selectivity to the mask 416 layer.

In addition to COS or CS₂ the stripping gas preferably comprises at least one of O₂, CO₂, N₂, or H₂. More preferably the stripping gas comprises a bombarding component such as Ar. More preferably, the stripping gas comprises O₂ or N₂. Most preferably, the stripping gas comprises O₂.

Other examples do not provide a passivation step or provide a passivation without a COS and CS₂ additive.

In one example, the hardmask can be amorphous carbon or it can contain Si incorporated into the amorphous carbon structure. Most preferably, the hardmask layer is amorphous carbon. Such a hardmask may be spun on or chemical vapor deposited (CVD) or may be deposited by other methods. In other examples, the hardmask layer has a carbon component, such as a carbon based hardmask, such as amorphous carbon, or a silicon based hardmask with a carbon component. The invention can be used in order to etch any aspect ratio feature in such a layer.

Preferably, the mask layer is of silicon oxide or SiON. Preferably, the mask layer and the etch layer have similar etch properties. Preferably, the hardmask layer may be selectively etched with respect to the mask layer and the etch layer may be selectively etched with respect to the hardmask layer.

Preferably, the invention provides a high aspect ratio etch of greater than 20:1. More preferably the invention provides a high aspect ratio etch of greater than 25:1.

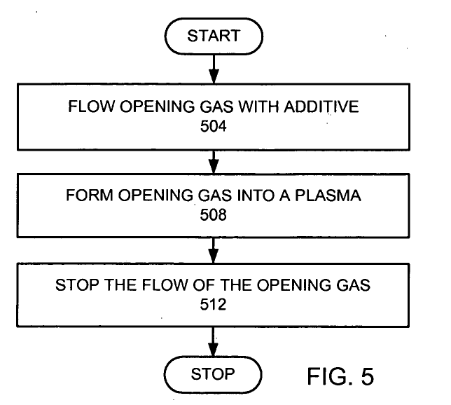

In accordance with one embodiment of the present invention, a multi-layer resist (MLR) mask is used in etching of an etch layer formed over a substrate. FIG. 6 schematically illustrates an example of multi-layer resist mask 600 formed on an etch layer 604 formed on a substrate 602. As shown in FIG. 6, the multi-layer resist mask 600 includes a spun-on carbon (SOC) layer 606 formed on the etch layer 604, an oxide-based material layer 608 disposed on the spun-on carbon layer 606, and a patterned mask 610 disposed on the oxide-based material layer 608.

For example, the patterned mask 610 may be a patterned photoresist (PR) mask having a thickness of about 120 nm. The PR mask 610 may be patterned with the immersion 193 nm photolithography having a CD about 70 nm. The oxide-based material layer 608 may be made of a SiO₂-based material, such as a spin-on glass (SOG) layer with a thickness of about 45 nm. The spun-on carbon layer 606 may be used as a hardmask in etching of the underlying etching layer 604, and may also be referred to as spun-on hardmask (SOH). The spun-on carbon layer 606 may have a thickness of about 350 nm. Compared with amorphous carbon in the previous embodiment, which typically requires a sputter film deposition process, the spun-on carbon layer is formed by spin coating using a conventional resist coater and thus less expensive. Spun-on carbon is more polymer-like and thus softer than amorphous carbon. Compared with other organic films, on the other hand, the spun-on carbon has higher concentration of carbon and lower concentration of oxygen. The spun-on carbon layer may be formed using an organic planarization material, such as NFC, available from JSR Micro, Inc., Sunnyvale, Calif., and other material such as—SOC (Spin-On Carbon), SOH (Spin-On Hardmask) available from Shipley Co. Inc., Marlborough, Mass., TOK, Japan, JSR Micro, Inc., and the like. The etch layer 604 may be a TEOS (tetra-ethyl-ortho-silicate, tetra-ethoxy-silane) or PE-TEOS layer having a thickness of about 400 nm. The substrate 602 may be made of SiN, or other silicon-based material. It should be noted that the present invention is not limited to specific materials of the etch layer or the substrate.

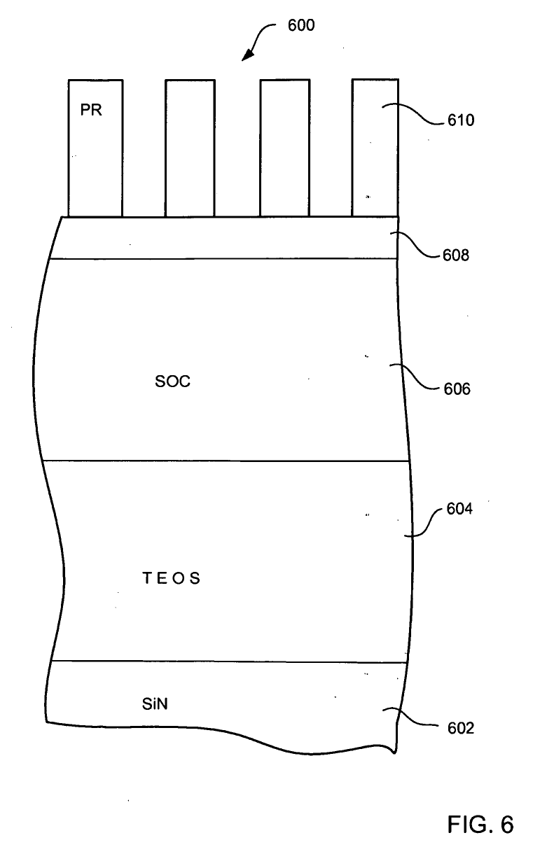

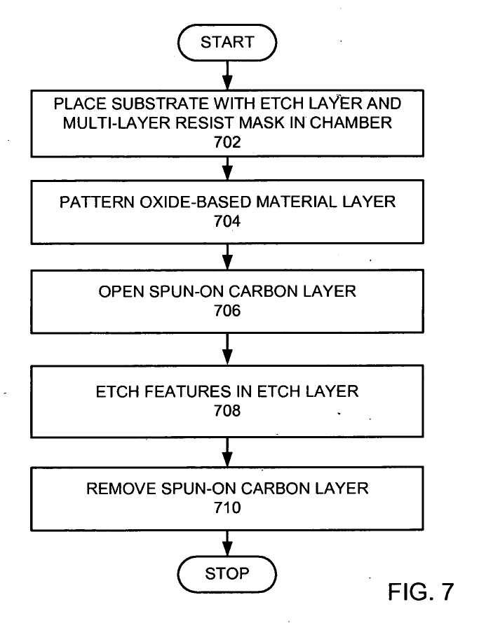

FIG. 7 is a high level flow chart of a process etching an etch layer formed on a substrate using a multi-layer resist mask in accordance with this embodiment of the invention. The multi-layer resist mask 600 and the etch layer 604 described above are used as an illustrative example. The substrate 602 with a stack of layers is placed in a plasma processing chamber (step 702). FIG. 8 is a schematic view of a plasma processing chamber 800 that may be used for the inventive etching in accordance with one embodiment of the present invention. The plasma processing chamber 800 comprises confinement rings 802, an upper electrode 804, a lower electrode 808, a gas source 810, and an exhaust pump 820 connected to a gas outlet. Within plasma processing chamber 800, the substrate 602 (with the stack of layers) is positioned upon the lower electrode 808. The lower electrode 808 incorporates a suitable substrate chucking mechanism (e.g., electrostatic, mechanical clamping, or the like) for holding the substrate 602. The reactor top 828 incorporates the upper electrode 804 disposed immediately opposite the lower electrode 808. The upper electrode 804, lower electrode 808, and confinement rings 802 define the confined plasma volume 840. Gas is supplied to the confined plasma volume 840 by the gas source 810 through a gas inlet (holes) 843 formed in the top electrode, dissociated into reactive plasma by the RF powers applied to the lower electrode, and then is exhausted from the confined plasma volume 840 through the confinement rings 802 and an exhaust port by the exhaust pump 820. Besides helping to exhaust the gas, the exhaust pump 820 helps to regulate pressure. In this embodiment, the gas source 810 comprises a patterning gas source 812, a hardmask opening gas source 814 and an etching gas source 816. The hardmask opening gas source may include a COS gas source, an O₂ gas source, and optionally other gas sources (not shown) depending on the opening gas recipe. The gas source 810 may further comprise other gas source(s) 818, such as a stripping gas source for the subsequent stripping processes for the hardmask to be performed in the processing chamber 800.

As shown in FIG. 8, an RF source 848 is electrically connected to the lower electrode 808. Chamber walls 852 surround the confinement rings 802, the upper electrode 804, and the lower electrode 808. The RF source 848 may comprise a 2 MHz power source, a 60 MHz power source, and a 27 MHz power source. Different combinations of connecting RF power to the electrode are possible. In the case of Lam Research Corporation's Dielectric Etch Systems such as Exelan® Series, made by LAM Research Corporation™ of Fremont, Calif., which may be used in a preferred embodiment of the invention, the 27 MHz, 2 MHz, and 60 MHz power sources make up the RF power source 848 connected to the lower electrode, and the upper electrode is grounded. A controller 835 is controllably connected to the RF source 848, exhaust pump 820, and the gas source 810. The controller 835 may be implemented in the same manner as the controller 235 described above referring to FIGS. 3A and 3B.

Referring back to FIG. 7, the oxide-based material layer 608 is patterned through the patterned PR mask 610 using a patterning gas (step 704). Any conventional gas suitable for etching/patterning the oxide-based material layer 608. The spun-on carbon layer 606 is then opened through the patterned oxide-based material layer 608 using a hardmask opening gas (step 706). In the opening step, the hardmask opening gas containing a COS component is introduced from the hardmask gas source into the plasma processing chamber. A plasma is formed from the hardmask opening gas so as to open (etch) the spun-on carbon layer. Then, the flow of the hardmask opening gas is stopped. In accordance with an embodiment of the present invention, the hardmask opening gas further includes O₂. Preferably, the hardmask opening gas consists essentially of O₂, COS, and a dilutant gas such as Ar. Alternatively, the hardmask opening gas may include COS, at least one of O₂, CO₂, N₂, or H₂, and optionally Ar. CO or CH₄ may further be added to the hardmask opening gas. In a preferable example, the hardmask opening gas contains about 100 to 400 sccm O₂ and about 1 to 50 sccm COS, preferably, about 5 to 20 sccm COS, more preferably about 10 sccm COS. Alternatively, COS may be about 1% to 25%, preferably 5% to 15%, more preferably about 10% of the total flow of the hardmask opening gas. An example recipe for a hardmask opening provides a chamber pressure of 20 mTorr. The electrostatic chuck temperature is maintained at 30° C. An upper electrode temperature is maintained at 110° C. An opening gas of 200 sccm O₂ and 10 sccm COS is provided.

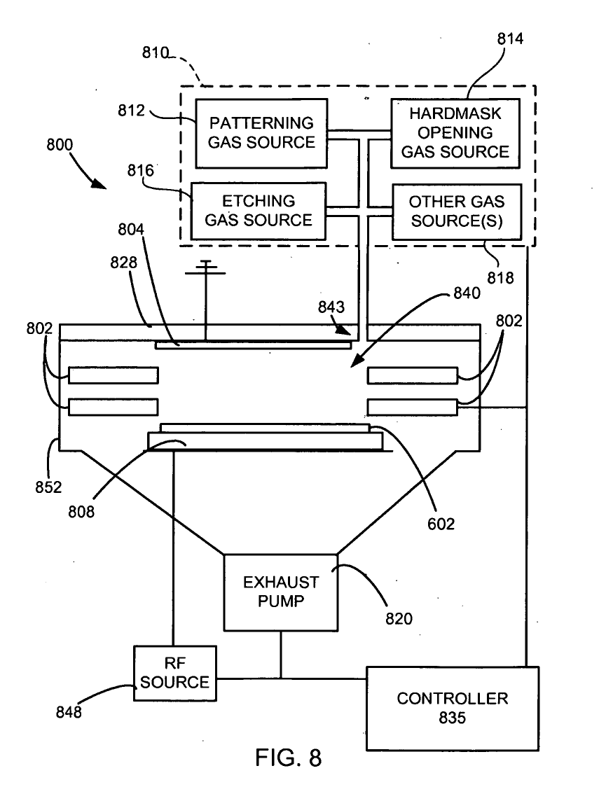

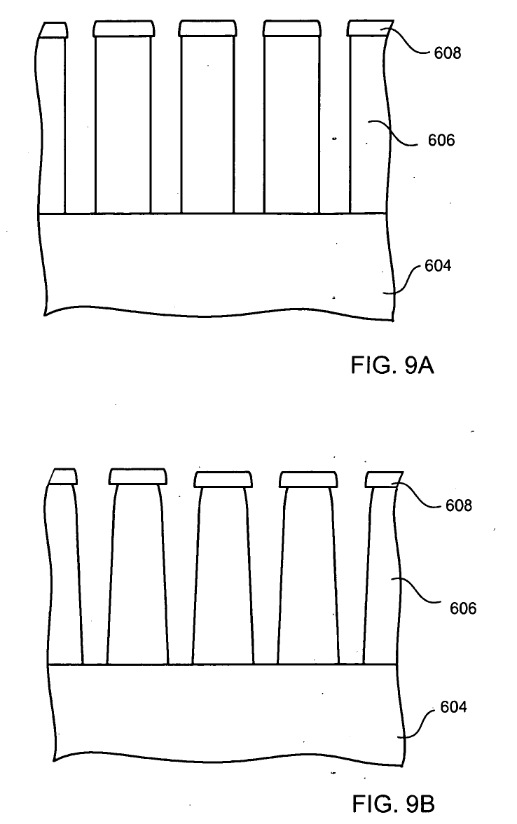

FIG. 9A schematically illustrates a cross-sectional view of the profile of the spun-on carbon layer after the opening process in accordance with one embodiment of the present invention. For comparison, FIG. 9B shows a schematic cross-sectional view of the profile of the spun-on carbon layer after a conventional opening process (without COS) as a reference. By adding COS to the hardmask opening gas, the profile of the spun-on carbon layer 606 is significantly improved. Since spun-on carbon is more like polymer and softer than amorphous carbon, it is believed that the spun-on carbon layer is more susceptible to undercut, bowing, tapering, and the like during the opening process. Applicants have tried various gases such as CH₃F, CH₄, C₂H₄ and CO as an additive to the hardmask opening gas to control the profile of the spun-on carbon layer, and found that COS unexpectedly improved the profile yet maintaining a high etch rate of the opening process. COS does not affect the etch rate as significantly as other additives.

Referring back to FIG. 7, using the thus opened spun-on carbon layer as a hardmask, features are etched into the etch layer 604 using an etching gas (step 708), by providing an etch gas from the etch gas source, forming a plasma from the etch gas, and stopping the etch gas. The etching of the etch layer may be performed in a similar manner as the previous embodiment, or may be performed using any conventional etch process suitable for the etch layer (TEOS in this example). In the subsequent process (step 710), the hardmask may be completely removed.

While this invention has been described in terms of several preferred embodiments, there are alterations, permutations. modifications, and various substitute equivalents, which fall within the scope of this invention. It should also be noted that there are many alternative ways of implementing the methods and apparatuses of the present invention. It is therefore intended that the following appended claims be interpreted as including all such alterations, permutations, and various substitute equivalents as fall within the true spirit and scope of the present invention.

What is claimed is:

1. A method for opening a carbon-based hardmask layer formed on an etch layer over a substrate, the hardmask layer disposed below a patterned mask, comprising:
placing the substrate in a plasma processing chamber; and
opening the hardmask layer, comprising:
flowing a hardmask opening gas including a COS component into the plasma chamber;
forming a plasma from the hardmask opening gas; and
stopping the flow of the hardmask opening gas.

2. The method as recited in claim 1, wherein the hardmask layer is made of amorphous carbon.

3. The method as recited in claim 1, wherein the hardmask layer is made of spun-on carbon.

4. The method as recited in any one of claims 1-3, wherein the hardmask opening gas further includes O₂.

5. The method as recited in claim 4, wherein the hardmask opening gas consists essentially of O₂, COS, and a dilutant gas.

6. The method as recited in any one of claims 1-3, wherein the hardmask opening gas further includes at least one of O₂, CO₂, N₂, or H₂.

7. The method as recited in any one of claims 1-6, wherein an oxide based material layer is provided between the patterned mask and the hardmask layer, the method further comprising: patterning the oxide-based material layer using the patterned mask,
and wherein the hardmask layer is opened through the patterned oxide-based material layer.

8. A method for opening a spun-on carbon layer in a multi-layer resist mask formed on an etch layer over a substrate, the multi-layer resist mask including the spun-on carbon layer, an oxide-based material layer disposed over the spun-on carbon layer, and a patterned mask disposed on the oxide-based material layer, the method comprising:
placing the substrate in a plasma processing chamber;
patterning the oxide-based material layer using the patterned mask; and
opening the spun-on carbon layer using the patterned oxide-based material layer, the opening comprising:
flowing a hardmask opening gas including a COS component into the plasma processing chamber;
forming a plasma from the hardmask opening gas; and
stopping the flow of the hardmask opening gas.

9. The method as recited in claim 8, wherein the hardmask opening gas further includes O₂.

10. The method as recited in claim 9, wherein the hardmask opening gas consists essentially of O₂, COS, and a dilutant gas.

11. The method as recited in claim 8, wherein the hardmask opening gas further includes at least one of O₂, CO₂, N₂, or H₂.

12. The method as recited in any one of claims 8-11, wherein COS is about 1% to 25% of the total flow of the hardmask opening gas.

13. The method as recited in claim 12, wherein COS is about 5% to 15% of the total flow of the hardmask opening gas.

14. The method as recited in claim 13, wherein COS is about 10% of the total flow of the hardmask opening gas.

15. A method for etching an etch layer over a substrate using a multi-layer resist mask formed thereon, the multi-layer resist mask including a spun-on carbon layer formed on the etch layer, an oxide-based material layer disposed on the spun-on carbon layer, and a patterned mask disposed on the oxide-based material layer, the method comprising:
placing the substrate in a plasma processing chamber;
patterning the oxide-based material layer using the patterned mask;
opening the spun-on carbon layer using the patterned oxide-based material layer, the opening comprising:
flowing a hardmask opening gas including a COS component into the plasma processing chamber;
forming a plasma from the hardmask opening gas; and
stopping the flow of the hardmask etching gas;
etching features into the etch layer through the opened spun-on carbon layer; and
removing the patterned spun-on carbon layer.

16. An apparatus for etching an etch layer over a substrate using a multi-layer resist mask formed thereon, the multi-layer resist mask including a spun-on carbon layer formed on the etch layer, an oxide-based material layer disposed on the spun-on carbon layer, and a patterned mask disposed on the oxide-based material layer, the apparatus comprising:
a plasma processing chamber, comprising:
a chamber wall forming a plasma processing chamber enclosure;
a substrate support for supporting a substrate within the plasma processing chamber enclosure;
a pressure regulator for regulating the pressure in the plasma processing chamber enclosure;
at least one electrode for providing power to the plasma processing chamber enclosure for sustaining a plasma;
at least one RF power source electrically connected to the at least one electrode;
a gas inlet for providing gas into the plasma processing chamber enclosure; and
a gas outlet for exhausting gas from the plasma processing chamber enclosure;
a gas source in fluid connection with the gas inlet, including a patterning gas source, an opening gas source and an etch gas source; and
a controller controllably connected to the gas source, the RF bias source, and the at least one RF power source, comprising:
at least one processor; and
computer readable media, comprising:
computer readable code for patterning the oxide-based material layer using the patterned mask;
computer readable code for opening the spun-on carbon layer using the patterned oxide-based material layer, comprising:
computer readable code for flowing a hardmask opening gas including a COS component into the plasma processing chamber;
computer readable code for forming a plasma from the hardmask opening gas; and
computer readable code for stopping the flow of the hardmask etching gas; and
computer readable code for etching features into the etch layer through the opened spun-on carbon layer, comprising:
computer readable code for providing an etch gas from the etch gas source;
computer readable code for forming a plasma from the etch gas; and
computer readable code for stopping the etch gas; and
computer readable code for removing the patterned spun-on carbon layer.

17. A method for etching an etch layer over a substrate and disposed below a hardmask layer disposed below a mask, comprising:
placing the substrate in a plasma processing chamber;
opening the hardmask layer, comprising:
flowing a hardmask opening gas with a COS or CS₂ component into the plasma chamber;
forming a plasma from the hardmask opening gas; and
stopping the flow of the hardmask opening gas;
etching features into the etch layer through the hardmask; and
removing the hardmask.

18. The method as recited in claim 17, wherein the hardmask comprises one of a carbon based material or a silicon doped carbon based material with a carbon component.

19. The method as recited in claim 18, wherein the hardmask layer is amorphous carbon.

20. The method as recited in claim 18, wherein the hardmask open gas further comprises at least one of O₂, CO₂, N₂, or H₂.

21. The method as recited in claim 20, wherein the hard mask open gas further comprises Ar.

22. The method as recited in any one of claims 17-21, wherein the mask is of a silicon oxide or SiON.

23. The method as recited in claim 22, wherein the etch layer is one of a silicon dioxide based material, organo-silicate glass, a silicon nitride based material, a silicon oxynitride based material, silicon carbide based material, silicon or poly-silicon material, or any metal gate material.

24. The method as recited in any one of claims 17-23, wherein the hardmask is of a carbon based material and wherein the removing the hardmask is an oxygen ashing and wherein the etch layer is a low-k dielectric layer, further comprising, passivating sidewalls of features etched into the said etch layer before removing the hardmask, comprising:
providing an ashing gas comprising oxygen with an additive of COS or CS₂;
forming a plasma from the ashing gas; and
stopping the ashing gas.

25. The method, as recited in any one of claims 17:24, wherein the hardmask opening gas has a COS component.

26. A semiconductor device made from the method recited in any one of claims 17-25.

27. An apparatus for etching high aspect ratio features in an etch layer above a substrate and below a carbon containing hardmask below a mask, comprising:
a plasma processing chamber, comprising:
a chamber wall forming a plasma processing chamber enclosure;
a substrate support for supporting a substrate within the plasma processing chamber enclosure;
a pressure regulator for regulating the pressure in the plasma processing chamber enclosure;
at least one electrode for providing power to the plasma processing chamber enclosure for sustaining a plasma;
at least one RF power source electrically connected to the at least one electrode;
a gas inlet for providing gas into the plasma processing chamber enclosure; and
a gas outlet for exhausting gas from the plasma processing chamber enclosure;
a gas source in fluid connection with the gas inlet, comprising:
an opening component source;
an etch gas source; and
an additive source; and
a controller controllably connected to the gas source, the RF bias source, and the at least one RF power source, comprising:
at least one processor; and
computer readable media, comprising:
computer readable code for opening the hardmask layer, comprising:
computer readable code for flowing a hardmask opening gas comprising an opening component of at least one of O₂, N₂, or H₂ from the opening component source with an additive of COS or CS₂ from the additive source into the plasma chamber;
computer readable code for forming a plasma from the hardmask opening gas; and
computer readable code for stopping the flow of the hardmask opening gas;
computer readable code for etching features into the etch layer through the hardmask, comprising
computer readable code for providing an etch gas from the etch gas source;
computer readable code for forming a plasma from the etch gas; and
computer readable code for stopping the etch gas; and
computer readable code for removing the hardmask.

28. The apparatus, as recited in claim 27, wherein the hardmask is of a carbon based material and wherein the removing the hardmask is an oxygen ashing and wherein the etch layer is a low-k dielectric layer, wherein the computer readable media further comprises, computer readable code for passivating sidewalls of features etched into the said etch layer before removing the hardmask, comprising:
computer readable code for providing an ashing gas comprising oxygen from the opening component source with an additive of COS or CS₂ from the additive source;
forming a plasma from the ashing gas; and
stopping the ashing gas.
